(19) United States
(12) Patent Application Publication
(10) Pub. No.: US 2013/0241734 A1
(43) Pub. Date: Sep. 19, 2013

(54) SYSTEM AND METHOD FOR DETECTING IMPROPER WIRING OR CONFIGURATION IN A MONITORING SYSTEM

(71) Applicants: Mitchell Dean Cohen, Carson City, NV (US); Michael Alan Tart, Gardnerville, NV (US); Robert Ronald Nikkels, Gardnerville, NV (US)

(72) Inventors: Mitchell Dean Cohen, Carson City, NV (US); Michael Alan Tart, Gardnerville, NV (US); Robert Ronald Nikkels, Gardnerville, NV (US)

(73) Assignee: General Electric Company, Schenectady, NY (US)

(21) Appl. No.: 13/421,452

(22) Filed: Mar. 15, 2012

(51) Int. Cl. G08B 21/00; G01R 31/00; G06F 19/00

(52) U.S. Cl. 340/635; 702/58

(57) ABSTRACT

A system and method for detecting improper wiring or configuration in a monitoring system. The improper wiring or configuration is detected by measuring the value of an electrical property (e.g., voltage or current) of an electrical signal received from a first set of wiring terminals to which a transducer is connected and comparing that value to a predetermined value or range of values of the electrical property based on values that would be expected for the electrical signal if the transducer was the type configured to be monitored by the monitoring unit.

### BACKGROUND OF THE INVENTION

The subject matter disclosed herein relates to a system and method for detecting improper wiring or configuration in a monitoring system.

Industrial manufacturing plants employ various types of sensors for monitoring the condition of assets. For example, transducers designed to monitor parameters of an asset (e.g., seismic transducers, proximity transducers, velocity transducers, etc.) can be coupled to the asset and communicate with a monitoring unit. Using information provided by the transducers, the monitoring unit can determine if the asset is experiencing an undesirable condition.

In some installations, the transducers communicate with the monitoring unit via input channels on an input/output (IO) module. Each transducer is connected to an input channel of the IO module by wires fastened to wiring terminals on a wiring terminal block for that input channel. Since some wiring terminal blocks for input channels have wiring terminals that can accommodate different types of transducers, typically, the wires from a particular type of transducer must be wired to particular wiring terminals. The monitoring unit is then configured to monitor that particular type of transducer on that input channel. While instructions are typically provided for wiring the different transducer types to different wiring terminals on a wiring terminal block, technicians often improperly connect the wiring from the transducer. For example, the wires from a velocity transducer may be improperly fastened to wiring terminals that were dedicated for a proximity transducer. Since the monitoring unit would be configured to monitor a velocity transducer as intended by the technician, but is instead monitoring a proximity transducer, errors will occur. These improper wiring connections can go undetected for significant periods of time.

The discussion above is merely provided for general background information and is not intended to be used as an aid in determining the scope of the claimed subject matter.

### BRIEF DESCRIPTION OF THE INVENTION

A system and method for detecting improper wiring or configuration in a monitoring system. The improper wiring or configuration is detected by measuring the value of an electrical property (e.g., voltage or current) of an electrical signal received from a first set of wiring terminals to which a transducer is connected and comparing that value to a predetermined value or range of values of the electrical property based on values that would be expected for the electrical signal if the transducer was the type configured to be monitored by the monitoring unit. An advantage that may be realized in the practice of some embodiments of the described system and method is the increased speed and accuracy of installing a transducer monitoring system by detecting incorrect wiring of transducers early in the installation process.

In one embodiment, a detection system for detecting improper wiring or configuration in a monitoring system is disclosed. The detection system comprises a first transducer wired to a first set of wiring terminals of a wiring terminal block of a first input channel of an input/output module, a monitoring unit configured for monitoring the first transducer, wherein the configuration of the monitoring unit comprises the type of transducer to be monitored on the first channel of the input/output module, a wiring detection module for measuring a value of an electrical property of an electrical signal received from the first set of wiring terminals, and a microprocessor for comparing the value of the electrical property of the electrical signal received from the first set of wiring terminals to a predetermined value or range of values of the electrical property, wherein the predetermined value or range of values of the electrical property is based on a value or range of values that would be expected for the electrical signal received from the first set of wiring terminals if the first transducer was the type of transducer configured to be monitored by the monitoring unit on the first channel of the input/output module.

In another embodiment, a method for detecting improper wiring or configuration in a monitoring system having a first transducer wired to a first set of wiring terminals of a wiring terminal block of a first input channel of an input/output module is disclosed. The method comprises the steps of configuring a monitoring unit for monitoring the first transducer, wherein the configuration of the monitoring unit comprises the type of transducer to be monitored on the first channel of the input/output module, measuring a value of an electrical property of an electrical signal received from the first set of wiring terminals, and comparing the value of the electrical property of the electrical signal received from the first set of wiring terminals to a predetermined value or range of values of the electrical property, wherein the predetermined value or range of values of the electrical property is based on a value or range of values that would be expected for the electrical signal received from the first set of wiring terminals if the first transducer was the type of transducer configured to be monitored by the monitoring unit on the first channel of the input/output module.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a schematic diagram of an exemplary monitoring system;

FIG. 2 is a plan view of the back side of an exemplary input/output module showing the input channel wiring terminal blocks; and

FIG. 3 is a flow diagram of an exemplary method for detecting improper wiring or configuration in a monitoring system having a transducer wired to a set of wiring terminals of a wiring terminal block of a first input channel of an input/output module.

### DETAILED DESCRIPTION OF THE INVENTION

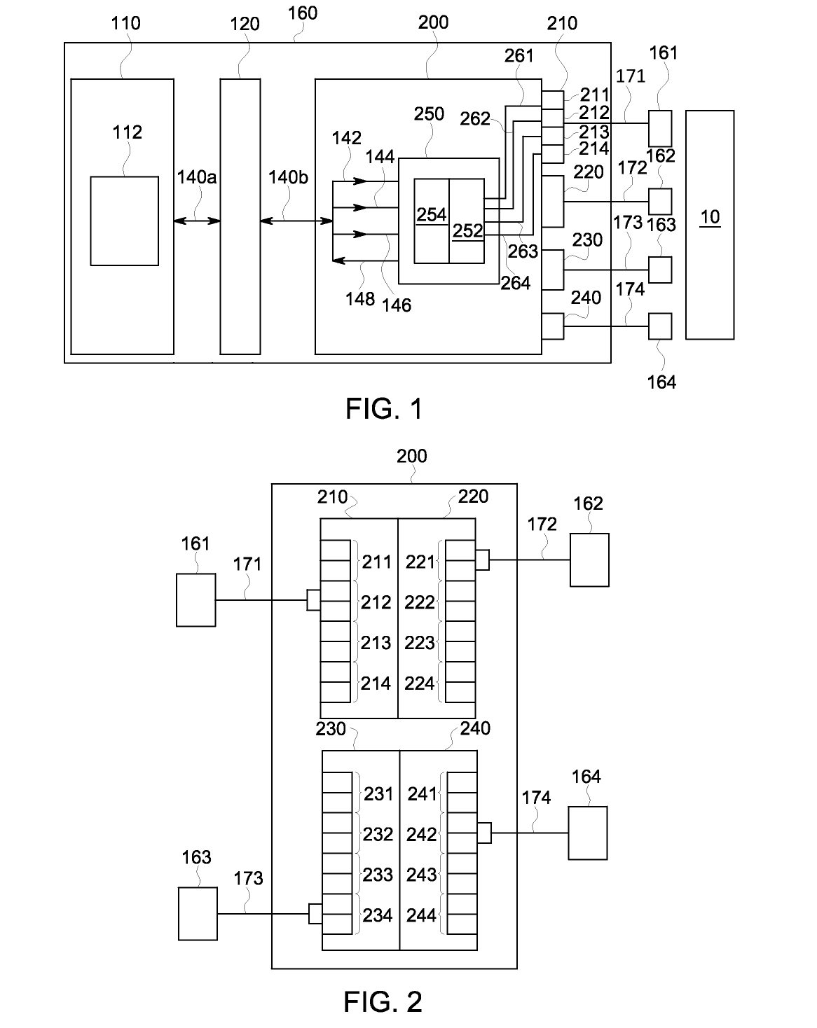

FIG. 1 is a schematic diagram of an exemplary monitoring system 100 for monitoring an asset 10 (e.g., power generating turbines, industrial pumps, processing equipment, etc.). The monitoring system 100 includes a rack 160 that houses a monitoring unit 110 that communicates with an input/output (IO) module 200 through a backplane 120 via a bus having a first section 140a and a second section 140b (together referred to as bus 140). In one embodiment, the bus 140 is a Serial Peripheral Interface (SPI) bus. In one embodiment, the bus 140 includes a data input line 142 (e.g., MOSI (Master Out Slave In)), a single device select line 144, a clock line 146, and a data output line 148 (e.g., MISO (Master In Slave Out)).

The IO module 200 communicates with a plurality of transducers (e.g., first transducer 161, second transducer 162, third transducer 163, and fourth transducer 164) coupled to the asset 10 to monitor the operation of the asset 10. A monitoring unit 110 is configured to provide a user with information regarding the parameters being monitored by the transducers 161-164. The monitoring unit 110 may comprise an illuminated display (e.g., a series of light emitting diodes (LEDs)) and/or may comprise a liquid crystal display or computer screen. The monitoring unit 110 can include a microprocessor 112 for analysis and triggering of alerts when maintenance is deemed necessary.

Each of the transducers 161-164 are connected to an input channel wiring terminal block (e.g., first input channel wiring terminal block 210, second input channel wiring terminal block 220, third input channel wiring terminal block 230, and fourth input channel wiring terminal block 240) on the back of the IO module using wiring (e.g., first transducer wiring 171, second transducer wiring 172, third transducer wiring 173, and fourth transducer wiring 174) from each of the transducers 161-164. Different types of transducers 161-164 can be used in the monitoring system 100. For example, proximity transducers can be used to monitor the movement of the asset or a component of the asset by measuring the distance between the transducer and the machine or component. Velocity transducers/accelerometers can be used to sense the speed of machine components. Similarly, seismic transducers can be used to monitor the vibration of a machine by measuring oscillatory motion. In one embodiment, two different seismic transducers types are used. The two seismic transducers types may differ in that one seismic transducer type is barrier-free while the other seismic transducer type has an electrical barrier, such as a zener diode.

FIG. 2 is a plan view of the back side of the exemplary IO module 200 showing the input channel wiring terminal blocks 210, 220, 230, 240. In one embodiment, the input channel wiring terminal blocks 210, 220, 230, 240 have designated terminals for wiring a particular type of transducer. Certain sets of wiring terminals can be designated for wiring to a plurality of transducer types (e.g., a jointly used terminal for multiple types of transducers). For example, the first input channel wiring terminal block 210 has first transducer type wiring terminals 211, second transducer type wiring terminals 212, third transducer type wiring terminals 213, and fourth transducer type wiring terminals 214. Similarly, the second input channel wiring terminal block 220 has first transducer type wiring terminals 221, second transducer type wiring terminals 222, third transducer type wiring terminals 223, and fourth transducer type wiring terminals 224. Likewise, the third input channel wiring terminal block 230 has first transducer type wiring terminals 231, second transducer type wiring terminals 232, third transducer type wiring terminals 233, and fourth transducer type wiring terminals 234. The fourth input channel wiring terminal block 240 has first transducer type wiring terminals 241, second transducer type wiring terminals 242, third transducer type wiring terminals 243, and fourth transducer type wiring terminals 244.

The technician installing the transducers 161-164 and the transducer wiring 171-174 to the IO module 200 can be provided with instructions identifying the particular wiring terminals for wiring the different types of transducers 161-164 to the input channel wiring terminal blocks 210, 220, 230, 240. For example, if the first transducer 161 is a second transducer type (e.g., a velocity transducer), the instructions can direct a technician to wire the first transducer wiring 171 to the second transducer type wiring terminals 212 of the first input channel wiring terminal block 210. Similarly, and as shown in FIG. 2, the second transducer wiring 172 from the second transducer 162 is wired to the first transducer type (e.g., proximity transducer) wiring terminals 221 of the second input channel wiring terminal block 220, the third transducer wiring 173 from the third transducer 163 is wired to the fourth transducer type (e.g., seismic transducer-barrier) wiring terminals 234 of the third input channel wiring terminal block 230, and the fourth transducer wiring 174 from the fourth transducer 164 is wired to the second transducer type (e.g., velocity transducer) wiring terminals 242 of the fourth input channel wiring terminal block 240. In one embodiment, the remaining terminals on the input channel terminal blocks 210, 220, 230, 240 can be left unconnected. It will be understood that some of the input channel wiring terminal blocks 210, 220, 230, 240 may not be wired to any transducers and that some can be wired to the same type of transducer.

The monitoring unit 110 can be configured to monitor the particular types of transducers 161-164 wired to the input channel wiring terminal blocks 210, 220, 230, 240. For example, the microprocessor 112 of the monitoring unit 110 can be configured to monitor the first transducer 161 on the first input channel as a second type of transducer (e.g., a velocity transducer). If the first transducer 161 is in fact a second type of transducer (e.g., a velocity transducer) as the monitor 110 has been configured, and the technician properly wires the first transducer wiring 171 to the second transducer type terminals 212 on the first input channel wiring terminal block 210 as instructed, then the monitoring system 100 should perform properly. If, however, the first transducer 161 is a second type of transducer (e.g., a velocity transducer) as the monitor unit 110 has been configured, but the technician improperly wires the first transducer wiring 171 to the first transducer type terminals 211 on the first input channel wiring terminal block 210 (terminals configured for a first type of transducer (e.g., a proximity transducer)), then the monitoring system 100 will not perform properly. Similarly, if the monitoring unit 110 is improperly configured to monitor the first transducer 161 on the first input channel as a first type of transducer (e.g., a proximity transducer), but the first transducer 161 is actually a second type of transducer (e.g., a velocity transducer), even though the technician properly wires the first transducer wiring 171 of the second type of transducer to the second transducer type terminals 212 on the first input channel wiring terminal block 210, then the monitoring system 100 will not perform properly. In order to detect any wiring or configuration errors, the exemplary IO module 200 shown in FIG. 1 comprises a wiring detection module 250.

In one embodiment, one or more of the input channel wiring terminal blocks 210, 220, 230, 240 are connected to a wiring detection circuit 252 of a wiring detection module 250. As shown in FIG. 1, the first input channel wiring terminal block 210 is connected to the wiring detection circuit 252, with a first transducer type circuit 261 connected to the first transducer type wiring terminals 211, a second transducer type circuit 262 connected to the second transducer type wiring terminals 212, a third transducer type circuit 263 connected to the third transducer type wiring terminals 213, and a fourth transducer type circuit 263 connected to the fourth transducer type wiring terminals 213. The wiring detection sensor 254 of the wiring detection module measures the values of one or more electrical properties (e.g., voltage or current) of the electrical signals received by the wiring detection circuit 252 from the transducer type wiring terminals 211-214. For example, the wiring detection sensor 254 can measure the wiring terminal value (voltage or current) of the electrical signal received by the wiring detection circuit 252 from the wiring terminals 211-214 of the first input channel wiring terminal block 210 to which the first transducer wiring 171 of the first transducer 161 is wired as shown in FIGS. 1 and 2. These measured wiring terminal values can be transmitted to the microprocessor 112 of the monitoring unit 110 for detecting whether the wiring and configuration for the first input channel is proper.

The wiring detection module 250 (including the wiring detection circuit 252 and wiring detection sensor 254) may be a single component or be comprised of multiple components. Examples of such components include resistors, analog to digital (AD) converters, complex programmable logic devices (CPLD), storage devices such as volatile and/or non-volatile memory, and sensors for sensing voltage, current, combination of voltage and current, or another electrical property. In one embodiment, the wiring detection circuit 252 can comprise a plurality of resistors in series or parallel (or a combination of both) with the input channel wiring terminals, while the wiring detection sensor 254 can comprise an AD converter for converting the analog measured wiring terminal values to digital form for transmission to the microprocessor 112 of the monitoring unit 110.

The microprocessor 112 of the monitoring unit 110 can compare the measured wiring terminal values to a predetermined wiring terminal value or range of values that would be expected if the transducer wiring and configuration was proper. For example, the microprocessor 112 of the monitoring unit 110 can be configured to monitor the first transducer 161 on the first input channel as a second type of transducer (e.g., a velocity transducer). In this configuration, the microprocessor 112 would expect to receive measured wiring terminal voltage or current values from the first transducer type wiring terminals 211, the third transducer type wiring terminals 213, and the fourth transducer type wiring terminals 214 of the first input channel wiring terminal block 210 equal to or within a range of predetermined wiring terminal values expected from unwired terminals, since all of those wiring terminals should not be wired to transducers if properly wired. The microprocessor 112 would expect to receive a measured wiring terminal voltage or current value from the second transducer type wiring terminals 212 of the first input channel wiring terminal block 210 equal to or within a range of predetermined wiring terminal values expected from wiring terminals wired to the second type of transducer if properly wired. The predetermined wiring terminal values can be programmed into and stored in non-volatile memory in the monitoring unit 110 or in the IO module 200. Although the monitoring system 100 has been described with the microprocessor 112 of the monitoring unit 110 performing the comparison of the measured wiring terminal value with a predetermined value, it will be understood that the operation may be performed on the IO module 200 or in the wiring detection module 250.

If one or more of these conditions are not met when the microprocessor 112 compares the measured wiring terminal values to predetermined wiring terminal values for a particular input channel as configured, the monitoring unit 110 can use its display to display an alarm (e.g., an error message or flashing LED) or use an audible device (e.g., speaker) to generate an alarm to notify the technician of the wiring or configuration error. Alternatively, if each of these conditions are met, the monitoring unit 110 can display a confirmation message to notify the technician that the wiring and configuration is correct.

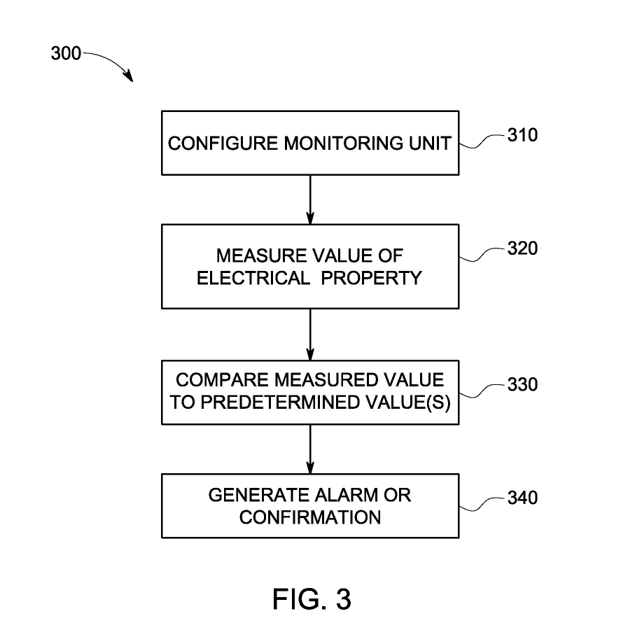

FIG. 3 is a flow diagram of an exemplary method 300 for detecting improper wiring or configuration in a monitoring system 100 having a first transducer 161 wired to a set of wiring terminals 211-214 of a wiring terminal block 210 of a first input channel of an input/output module 200. It will be understood that the steps of the exemplary method 300 can be practiced in a different order than shown in FIG. 3. At step 310, the monitoring unit 110 is configured for monitoring the first transducer, wherein the configuration of the monitoring unit comprises the type of transducer to be monitored on the first channel of the input/output module. Either before or after step 310, at step 320, the wiring detection module 250 measures a value of an electrical property of an electrical signal received from the first set of wiring terminals 212. At step 330, the microprocessor 112 of the monitoring unit 110 compares the value of the electrical property of the electrical signal received from the first set of wiring terminals 212 to a predetermined value or range of values of the electrical property, wherein the predetermined value or range of values of the electrical property is based on a value or range of values that would be expected for the electrical signal received from the first set of wiring terminals 212 if the first transducer 161 was the type of transducer configured to be monitored by the monitoring unit 110 on the first channel of the input/output module 110. At step 340, if the value of the electrical property of the electrical signal received from the first set of wiring terminals 212 is not equal to a predetermined value of the electrical property or outside the range of predetermined values of the electrical property, the monitoring unit 110 generates a visual or audible alarm to notify the technical of the error in wiring or configuration. If the if the value of the electrical property of the electrical signal received from the first set of wiring terminals 212 is equal to a predetermined value of the electrical property or within the range of predetermined values of the electrical property, the monitoring unit 110 generates a wiring confirmation indication (e.g., green LED light) to notify the technician that the wiring and configuration is correct.

In view of the foregoing, embodiments of the system and method for detecting improper wiring of a transducer to an input/output module in a monitoring system provide an indication to a technician that a transducer has been improperly wired. The technical effect is to increase the speed and accuracy of installing a transducer monitoring system by detecting incorrect wiring of transducers early in the installation process.

As will be appreciated by one skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.), or an embodiment combining software and hardware aspects that may all generally be referred to herein as a “service,” “circuit,” “circuitry,” “module,” and/or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Program code and/or executable instructions embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer (device), partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described herein with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A detection system for detecting improper wiring or configuration in a monitoring system, the detection system comprising
a first transducer wired to a first set of wiring terminals of a wiring terminal block of a first input channel of an input/output module;
a monitoring unit configured for monitoring the first transducer, wherein the configuration of the monitoring unit comprises the type of transducer to be monitored on the first channel of the input/output module;
a wiring detection module for measuring a value of an electrical property of an electrical signal received from the first set of wiring terminals; and
a microprocessor for comparing the value of the electrical property of the electrical signal received from the first set of wiring terminals to a predetermined value or range of values of the electrical property,
wherein the predetermined value or range of values of the electrical property is based on a value or range of values that would be expected for the electrical signal received from the first set of wiring terminals if the first transducer was the type of transducer configured to be monitored by the monitoring unit on the first channel of the input/output module.

2. The detection system of claim 1, wherein the wiring detection module comprises:
a wiring detection circuit for receiving the electrical signal from the first set of wiring terminals, wherein the wiring detection circuit is connected to the first set of wiring terminals of the wiring terminal block of the first input channel of the input/output module; and
a wiring detection sensor for measuring the value of the electrical property of the electrical signal received from the first set of wiring terminals.

3. The detection system of claim 2, wherein the wiring detection circuit comprises a plurality of resistors.

4. The detection system of claim 2, wherein the wiring detection sensor comprises an analog-to-digital converter.

5. The detection system of claim 1, wherein the electrical property of the electrical signal received from the first set of wiring terminals is voltage.

6. The detection system of claim 1, wherein the electrical property of the electrical signal received from the first set of wiring terminals is current.

7. The detection system of claim 1, wherein the transducer is selected from the group consisting of a proximity transducer, a velocity transducer, and a seismic transducer.

8. The detection system of claim 1, wherein microprocessor is part of the monitoring unit.

9. The detection system of claim 1, wherein microprocessor is part of the input/output module.

10. The detection system of claim 1, further comprising non-volatile memory for storing the predetermined value or range of values of the electrical property.

11. The detection system of claim 1, wherein the monitoring unit further comprises a display for displaying an alarm if the value of the electrical property of the electrical signal received from the first set of wiring terminals is not equal to a predetermined value of the electrical property or outside the range of predetermined values of the electrical property.

12. The detection system of claim 1, wherein the monitoring unit further comprises an audible device for generating an alarm if the value of the electrical property of the electrical signal received from the first set of wiring terminals is not equal to a predetermined value of the electrical property or outside the range of predetermined values of the electrical property.

13. The detection system of claim 1, wherein the monitoring unit further comprises a display for displaying a wiring confirmation indication if the value of the electrical property of the electrical signal received from the first set of wiring terminals is equal to a predetermined value of the electrical property or within the range of predetermined values of the electrical property.

14. A method for detecting improper wiring or configuration in a monitoring system having a first transducer wired to a first set of wiring terminals of a wiring terminal block of a first input channel of an input/output module, the method comprising the steps of:
configuring a monitoring unit for monitoring the first transducer, wherein the configuration of the monitoring unit comprises the type of transducer to be monitored on the first channel of the input/output module;
measuring a value of an electrical property of an electrical signal received from the first set of wiring terminals; and
comparing the value of the electrical property of the electrical signal received from the first set of wiring terminals to a predetermined value or range of values of the electrical property, wherein the predetermined value or range of values of the electrical property is based on a value or range of values that would be expected for the electrical signal received from the first set of wiring terminals if the first transducer was the type of transducer configured to be monitored by the monitoring unit on the first channel of the input/output module.

15. The method of claim 14, further comprising the step of generating a visual or audible alarm if the value of the electrical property of the electrical signal received from the first set of wiring terminals is not equal to a predetermined value of the electrical property or outside the range of predetermined values of the electrical property.

16. The method of claim 14, further comprising the step of generating a wiring confirmation indication if the value of the electrical property of the electrical signal received from the first set of wiring terminals is equal to a predetermined value of the electrical property or within the range of predetermined values of the electrical property.

17. The method of claim 14, wherein the electrical property of the electrical signal received from the first set of wiring terminals is voltage.

18. The method of claim 14, wherein the electrical property of the electrical signal received from the first set of wiring terminals is current.

19. The method of claim 14, wherein the transducer is selected from the group consisting of a proximity transducer, a velocity transducer, and a seismic transducer.
